(19) United States
(12) Patent Application Publication
(10) Pub. No.: US 2011/0267089 A1
(43) Pub. Date: Nov. 3, 2011

(54) TESTING BOARD

(76) Inventor: WEN CHYI CHEN, Hsinchu County (TW)

(21) Appl. No.: 13/092,950

(22) Filed: Apr. 24, 2011

(30) Foreign Application Priority Data
Apr. 28, 2010 (TW) 99113511

(51) Int. Cl. G01R 31/00

(52) U.S. Cl. 324/756.07

(57) ABSTRACT

The testing board is used to carry electrical device for electric testing. The testing board is constructed by a main testing board and a supporting board assembled on the lower surface of the main testing board. The main testing board and the supporting board respectively have a first thickness and a second thickness. The sum of the first thickness and the second thickness is matching the required distance of a testing apparatus.

### BACKGROUND OF THE INVENTION

1. Field of the Invention

The present invention is a testing board; especially, the present invention relates to a testing board formed by assembling at least two boards.

2. Description of Related Art

In semiconductor industry, it is necessary to test the function of chip or device in the manufacturing processes. With the development of the multi-function of IC, the high testing precision is required to sure that the electric function is achieved.

A testing tool of an electric testing apparatus is used for fixing a traditional testing board. Pressing members move downwardly to abut against the traditional testing board so that the traditional testing board is held between the pressing members and the testing tool. Therefore, the traditional testing board has a thickness to match the distance for fixing the traditional testing board by the pressing members and the testing tool.

However, the thickness of the traditional testing board is considered as a thicker thickness which results in the following disadvantages:

1. The traditional testing board has interconnections formed by via-hole and metal-plating processes, and the via-hole of the traditional testing board has high aspect ratio due to the thicker thickness of the traditional testing board. The high aspect ratio may result in the low manufacturing yield in metal-plating process.

2. With the complex data-computing, the electric testing may be applied in high frequency. The traditional testing board fails to be used in high frequency application because of its thicker thickness.

3. The traditional testing board is made by laminating substrates and it is not easy to control the surface roughness of the formed testing board. When the surface is rough, the precision of the testing result is low.

Consequently, with regard to the resolution of defects illustrated hereinbefore, the inventors of the present invention propose a reasonably and effectively designed solution for effectively eliminating such defects.

### SUMMARY OF THE INVENTION

The objective of the present invention is to provide a testing board is constructed by a main board and a supporting board. The sum of the thickness of the main board and the thickness of the supporting board matches the predetermined distance of the electric testing apparatus. Therefore, the main board has thinner thickness than the traditional testing board, and the thinner main board has improved testing precision and can be used in high frequency application.

Another objective of the present invention is to provide a testing board is constructed by a main board and a supporting board, characterized in the supporting board having receiving rooms for receiving the electronic components. Therefore, the testing board of the present invention has more efficient function area.

To achieve the objective described as above, the present invention discloses a testing board used to carry electronic device for electric testing. The testing board is positioned on a supporting surface of a testing tool. A pressing member abuts against an upper surface of the testing board, and a predetermined distance is formed between an abutting position of the pressing member and the supporting surface of the testing tool. The testing board includes a main board and a supporting board. The supporting board is assembled on a lower surface of the main board. The main board has a first thickness, and the supporting board has a second thickness. The sum of the first thickness and the second thickness is equal to the predetermined distance.

The total thickness of the testing board can match the thickness requirement for testing the electric function of the electronic device. The main board which has circuit function thereon is a thinner board than the traditional testing board; therefore, the main board of the present invention has higher manufacturing yield in via-hole and metal-plating processes. On the other hand, the supporting board is made by rigid materials so as to have higher structural strength and more smooth contact surface. Accordingly, the electronic device can be tested in a better testing environment and the testing result has higher precision.

On the other hand, the supporting board which has no circuit function thereon has different structures. In an embodiment, the supporting board has receiving rooms for electric components. That is means more electric components can be mounted on the testing board and more testing functions is achieved.

In order to further appreciate the characteristics and technical contents of the present invention, references are hereunder made to the detailed descriptions and appended drawings in connection with the present invention. However, the appended drawings are merely shown for exemplary purposes, rather than being used to restrict the scope of the present invention.

### BRIEF DESCRIPTION OF THE DRAWINGS

FIG. 1 is exploded diagrams of testing board which is held on the testing tool according to the present invention;

FIG. 2 shows the cross-sectional structure of testing board and testing tool according to the present invention; and

FIG. 3 shows the cross-sectional structure of testing board of the second embodiment and testing tool according to the present invention.

### DETAILED DESCRIPTION OF THE PREFERRED EMBODIMENTS

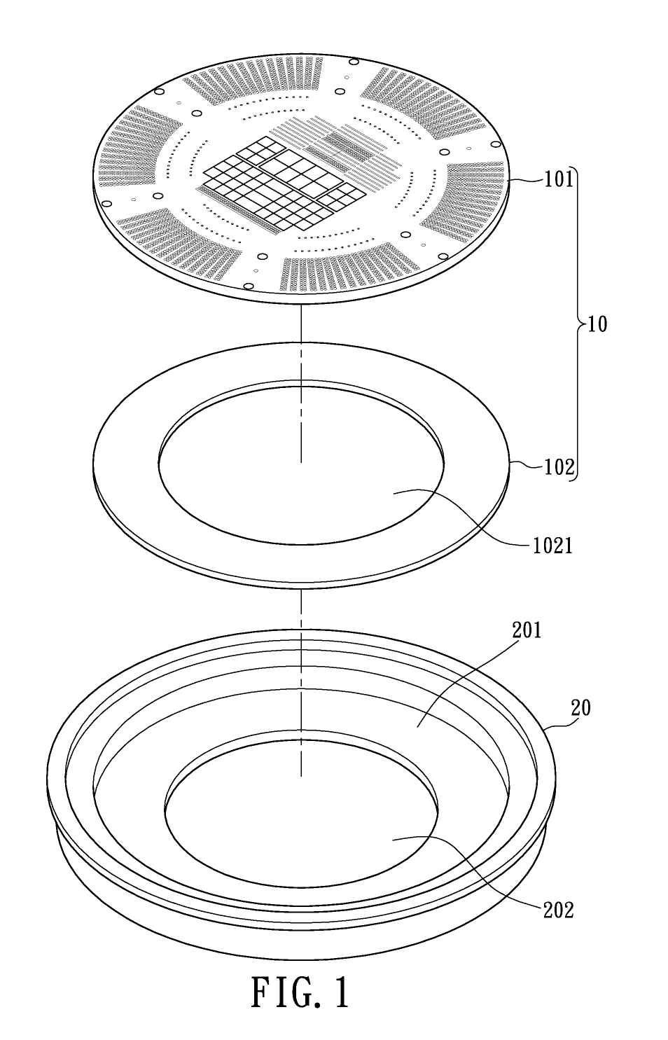

Please refer to FIG. 1; the testing board 10 of the first embodiment of the present invention is shown. The testing board 10 is constructed by at least two boards; for example, the testing board 10 of the first embodiment has two boards of a main board 101 with electric circuit function and a supporting board 102 with non-electric function. The testing board 10 is used on an electric testing apparatus, and the testing board 10 has to meet the thickness requirement of the electric testing apparatus. In other words, the thickness sum of the main board 101 and a supporting board 102 may be equal to the thickness requirement of the electric testing apparatus (i.e., a predetermined distance) for a more precise testing result.

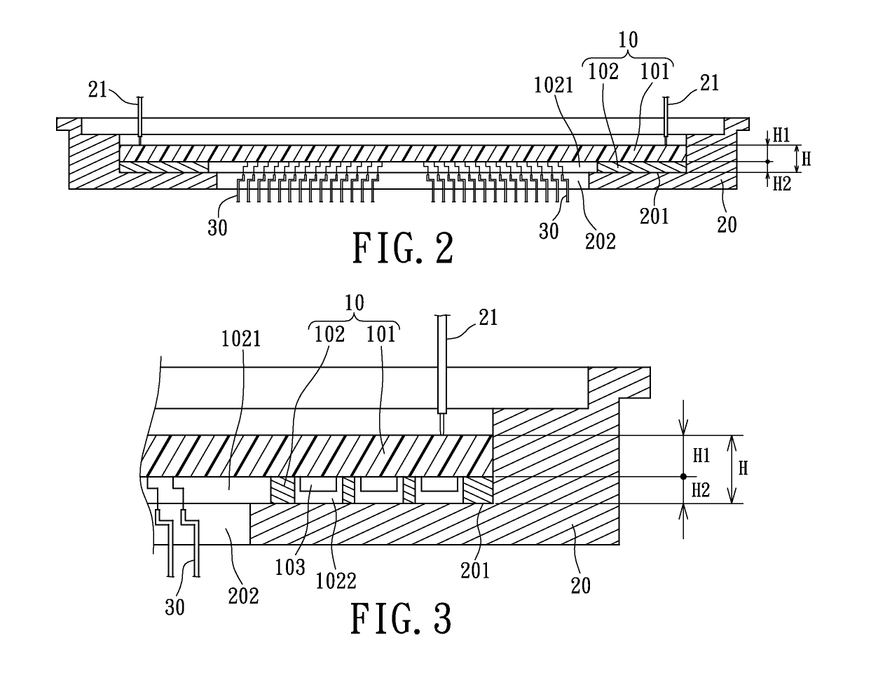

Please refer to FIG. 2; a testing tool 20 (i.e., a Ring Insert) is shown and used in an electric testing apparatus. The testing board 10 of the first embodiment is positioned on the testing tool 20. In detail, the testing board 10 is positioned on a supporting surface 201 of the testing tool 20, and a pressing member 21 (i.e. POGO PIN) of the electric testing apparatus may downward abut against an upper surface of the testing board 10. Accordingly, when the pressing member 21 reaches an abutting position, the testing board 10 is fixedly hold between the pressing member 21 and the supporting surface 201 of the testing tool 20 so that the testing probes 30 may contact the main board 101 of testing board 10 to perform an electric function testing. For the electric testing apparatus, the predetermined distance “H” is formed the position of pressing member 21 abutting on the testing board 10 between the supporting surface 201 of the testing tool 20. Different electric testing apparatuses may have different predetermined distances, and the testing board 10 of the present invention constructed by the main board 101 and the supporting board 102 to meet the distance requirement of electric testing apparatuses. In other words, the main board 101 which is thinner than a traditional testing board can be assembled with the supporting board(s) 102 with different thicknesses to match the above-mentioned distance of the electric testing apparatus.

An electric testing apparatus with H=6.5 mm is taken as an example. In other words, the predetermined distance of the abutting position of pressing member 21 of the pressing member 21 between the supporting surface 201 of the testing tool 20 of the example testing apparatus is 6.5 mm. It is necessary to choice a traditional testing board having a thickness of 6.5 mm for testing the electric function of the electronic device carried thereon. As described in “Description of Related Art”, the thinker PCB has electric issues in via-hole and metal-plating processes, or is not suitable-operated in high frequency application. On the contrary, the main board 101 with thinner first thickness “H1” and the supporting board 102 with corresponding second thickness “H2” are constructed as the testing board 10 of the present invention. In the embodiment, HI of the main board 101 is 0.4 mm to 6.0 mm and H2 is used to compensate the rest thickness of the thickness of (6.5 mm-H1). Therefore, the thinner main board 101 of the present invention has higher manufacturing yield in via-hole and metal-plating processes, and is more suitable in high operating frequency.

On the other hand, the supporting board 102 is fixed on the lower surface of the main board 101; for example, the supporting board 102 is attached or screwed on the lower surface of the main board 101. The main board 101 may be a substrate with circuit thereon, such as a PCB, a flexible printed circuit (FPC), flexible/rigid PCB, ceramic substrate, multi-chip module board, or universal board. The main board 101 further has a slot for inserting and carrying the electronic device. In addition, the supporting board 102 may be made by rigid materials or insulating materials, such as glass material or ceramic material so that the supporting board 102 has enough structural strength. In other words, the supporting board 102 may provide the strength for preventing from the deformation of the testing board 10. Moreover, the supporting board 102 may have smooth upper and bottom surfaces so that the horizontal leveling of the main board 101 can be achieved. Therefore, the electronic device carried on the main board 101 is tested in a desired testing environment. Accordingly, the testing board 10 with an electronic device thereon is held on the supporting surface 201 of the testing tool 20 in an electric testing apparatus. The testing tool 20 has a first opening 202 on the center portion thereof, and the supporting board 102 has a second opening 1021 corresponding to the first opening 202. Testing probes may move upward or downward to penetrate through the first opening 202 and the second opening 1021 to contact the lower surface of the main board 101 for performing an electric testing of the electronic device on the main board 101.

In the second embodiment of the present invention, the supporting board 102 further has at least one receiving room 1022. As shown in FIG. 2, three receiving rooms 1022 are formed on the supporting board 102, in which the electrical components 103 mounted on the lower surface of the main board 101 are accommodated. Therefore, the overlay area of the main board 101 and the testing tool 20 may be used to mount electrical components 103, and the mounted components 103 take no influence to the horizontal leveling of the main board 101. In other words, the main board 101 may have more electrical components 103 thereon and have more efficient area due to the receiving room 1022 of the supporting board 102.

To summarized, the testing board 10 is constructed by assembling the main board 101 and the supporting board 102. The main board 101 is a substantial circuit board and has thinner thickness than the traditional testing board so that the main board 101 of the present invention can have better manufacturing yield in via-hole and metal-plating processes. Furthermore, the electric function of the main board 101 is improved and the main board 101 can be more suitable for the high frequency application. In addition, the supporting board 102 can compensate the thickness of the testing board 10 so as to match the predetermined distance “H” of the electric testing apparatus. Moreover, the testing board 10 may have more leveling and smooth surface because of the rigidity of the supporting board 102 so that the testing result can be more precise. Still further, the supporting board 102 may have receiving rooms 1022 for receiving electrical components 103 mounted on the lower surface of the main board 101; therefore, the main board 101 can have more electrical components 103 thereon for increasing the circuit functions.

The above-mentioned descriptions represent merely the preferred embodiment of the present invention, without any intention to limit the scope of the present invention thereto. Various equivalent changes, alternations, or modifications based on the claims of present invention are all consequently viewed as being embraced by the scope of the present invention.

What is claimed is:

1. A testing board used to carry electronic device for electric testing, the testing board being positioned on a supporting surface of a testing tool, a pressing member abutting against an upper surface of the testing board, a predetermined distance being formed between an abutting position of the pressing member and the supporting surface of the testing tool;
the testing board characterized in that the testing board includes a main board and a supporting board, the supporting board is assembled on a lower surface of the main board, the main board has a first thickness, the supporting board has a second thickness, and a sum of the first thickness and the second thickness is equal to the predetermined distance.

2. The testing board according to claim 1, wherein the main board is a printed circuit board.

3. The testing board according to claim 2, wherein the testing tool has a first opening, and testing probes penetrate through the first opening to contact the lower surface of the main board.

4. The testing board according to claim 3, wherein the supporting board has a second opening corresponding to the first opening.

5. The testing board according to claim 1, wherein the supporting board has at least one receiving room for receiving electrical components mounted on the lower surface of the main board.

6. The testing board according to claim 1, wherein the supporting board is made by a rigid material.

7. The testing board according to claim 1, wherein the supporting board is fixed on the lower surface of the main board.

8. The testing board according to claim 7, wherein the supporting board is attached or screwed on the lower surface of the main board.
